(19) United States
(12) Patent Application Publication
(10) Pub. No.: US 2008/0230803 A1
(43) Pub. Date: Sep. 25, 2008

(54) Integrated Contact Interface Layer

(75) Inventors: Cedric Monier, Redondo Beach, CA (US); Randy Sandhu, Castaic, CA (US); Abdullah Cavus, Redondo Beach, CA (US); Augusto Gutierrez-Aitken, Redondo Beach, CA (US)

Correspondence Address: MILLER IP GROUP, PLC;NORTHROP GRUMMAN CORPORATION, 42690 WOODWARD AVENUE, SUITE 200, BLOOMFIELD HILLS, MI, 48304, US

(73) Assignee: Northrop Grumman Space & Mission Systems Corp., Los Angeles, CA (US)

(21) Appl. No.: 11/689,945

(22) Filed: Mar. 22, 2007

(51) Int. Cl. H01L 29/737; H01L 21/331

(52) U.S. Cl. 257/190; 438/312; 257/E29.193; 257/E21.371

(57) ABSTRACT

A semiconductor device that is fabricated by metamorphic epitaxial growth processes, and includes a combined graded base and active layer having a thickness less than 5000 Å. In one non-limiting embodiment, the semiconductor device is an HBT device that includes a combined doped graded buffer and sub-collector layer having a thickness less than 5000 Å, and a concentration of indium of about 86% at a top of the combined layer.

### GOVERNMENT CONTRACT

The U.S. Government may have a paid-up license in this invention and the right in limited circumstances to require the patent owner to license others on reasonable terms as provided for by the terms of Contract No. ONR N00014-01-2-0014, DARPA ABCS Program award by DARPA.

### BACKGROUND OF THE INVENTION

1. Field of the Invention

This invention relates generally to a semiconductor device that includes a combined graded buffer and active layer and, more particularly, to a heterojunction bipolar transistor (HBT) device that includes a combined and doped graded buffer and sub-collector layer deposited on a substrate by a metamorphic epitaxial growth process.

2. Discussion of the Related Art

Metamorphic epitaxial growth processes for fabricating semiconductor devices typically refers to depositing a semiconductor material on a substrate whose lattice parameter or atomic spacing does not match the lattice parameter of the substrate semiconductor material. Metamorphic epitaxial growth processes can provide high performance semiconductor devices having lattice parameters close to indium arsenide (InAs) compared to conventional epitaxial growth processes that provide lattice matched semiconductor devices deposited on semi-insulating substrates. Device performance improvements provided by metamorphic growth processes include low turn on voltages, low operating voltages and higher device speeds.

As the metamorphic epitaxial layers are deposited on the substrate and the thickness of the layer increases, the layer becomes strained as a result of the lattice parameter mismatch, which causes lattice structure relaxation and dislocations, and other lattice defects. Semiconductor devices that are fabricated using metamorphic epitaxial processes sometimes require a graded buffer layer between the substrate and the active layers of the device to match the semiconductor materials in the substrate to the active layers. Known metamorphic deposition processes attempt to confine the lattice structure relaxation at the beginning of the buffer layer to keep the dislocations confined within the buffer layer, and not let them propagate to the surface of the buffer layer adjacent to the active layers. However, some of the defects do propagate to the surface of the buffer layer. One way to minimize dislocation density in the buffer layer near the active layers is to increase the thickness of the graded buffer layer. Therefore, known semiconductor devices fabricated by metamorphic epitaxial processes typically required a relatively thick undoped graded buffer layer (GBL) between the substrate and the active layers, generally on the order of 1.5 to 2 μm thick, to provide a virtual platform for subsequent device epitaxial layers. However, thick metamorphic layers have high thermal resistances as a result of alloy scattering and materials defects that leads to higher junction temperatures at normal device operation conditions, thus impacting device performance and reliability.

For example, a HBT device including an InAlAs sub-collector layer and collector layer deposited on an InP semi-insulating substrate required a graded buffer layer to be deposited between the substrate and the sub-collector layer to match the lattice structure of the substrate to the lattice structure of the sub-collector layer. The graded buffer layer could be any combination of group III-V ternary or quaternary material systems, including, but not limited to, InAlAs, InGaAs, InAsP, InAsSb, InGaAlAs, InGaAsP, etc., at the interface between the substrate and the graded buffer layer, where the concentration of indium and gallium changes across the buffer layer until the graded buffer layer is InAlAs at the interface between the graded buffer layer and the sub-collector layer. HBT devices that employ relatively thick buffer layers are not only penalized by thermal properties, but also require a larger device process area than conventional lattice-matched technology because extra material needs to be removed to ensure device isolation when a wet etch is used with lateral etch effect.

FIG. 1 is a side view of a known metamorphic HBT device 10 including an indium phosphide semi-insulating substrate 12. The device 10 is described a specific example for any suitable III-V system. A graded buffer layer 14 is grown on the substrate 12 by a metamorphic epitaxial growth process. Other layers grown on the graded buffer layer 14 are lattice matched to the final buffer composition. The graded buffer layer 14 is undoped, and has a thickness upwards of 2 μm. The epitaxial growth process used to generate the graded buffer layer 14 provides an indium phosphide composition adjacent to the substrate 12. As the graded buffer layer 14 is deposited, the indium concentration is increased and the phosphide is removed so that a top portion of the graded buffer layer 14 will be In_{0.86}Al_{0.14}As. The composition of indium is 86% in this example, however, it can be graded up to 100%. The composition grading of indium is by way of example in that other group III-V ternary and quaternary semiconductor material systems can be used. An InAlAs sub-collector layer 16 is deposited on the graded buffer layer 14, where the sub-collector layer 16 is doped with silicon, and an InAlAs collector layer 18 is deposited on the sub-collector layer 16 where the collector layer 18 is doped with silicon. An InGaAs base layer 20 is then deposited on the collector layer 18 and an InAlAs emitter layer 22 is deposited on the base layer 20, where the base layer 20 is doped with beryllium and the emitter layer 22 is doped with silicon. The sub-collector layer 16 is contacted by a metal 24 and the base layer 20 is contacted by metals 26 and 28, which can be a single metal. This approach can be applicable to other group IV and group III-V semiconductor material systems.

### SUMMARY OF THE INVENTION

In accordance with the teachings of the present invention, a semiconductor device is disclosed that is fabricated by metamorphic epitaxial growth processes, and includes a combined and doped graded buffer and active layer having a thickness less than 5000 Å. In one non-limiting embodiment, the semiconductor device is a HBT device that includes a combined doped and graded buffer and sub-collector layer having a thickness less than 5000 Å, and a concentration of indium of about 86% at a top of the combined layer. Other concentrations of indium can be used up to 100%.

Additional features of the present invention will become apparent from the following description and appended claims, taken in conjunction with the accompanying drawings.

### BRIEF DESCRIPTION OF THE DRAWINGS

FIG. 1 is a side plan view of a heterojunction bipolar transistor having a convention or standard graded buffer layer of the type known to those skilled in the art; and

FIG. 2 is a side view of a heterojunction bipolar transistor that is fabricated by metamorphic epilayer growth processes, and includes a combined doped graded buffer and sub-collector layer, according to an embodiment of the invention.

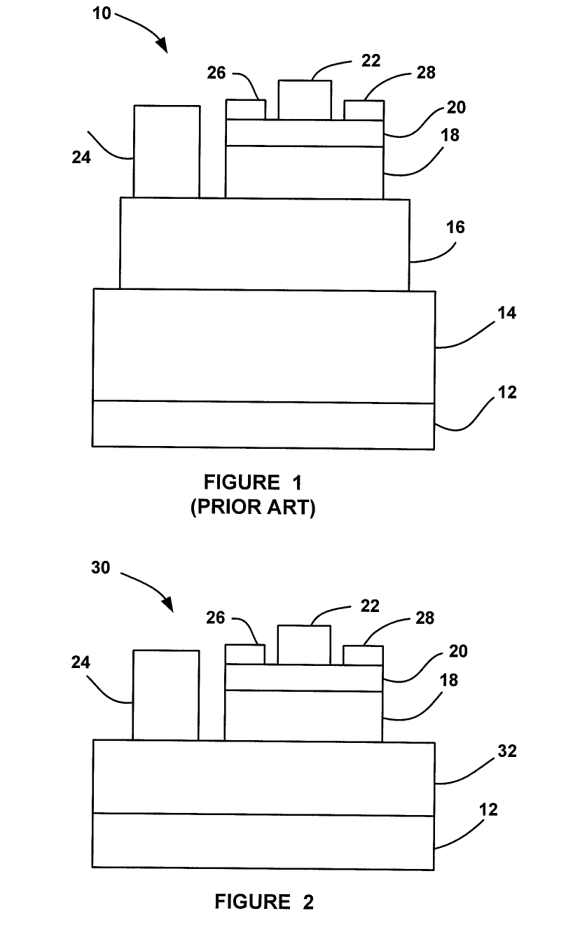

### DETAILED DESCRIPTION OF THE EMBODIMENTS

The following discussion of the embodiments of the invention directed to a semiconductor device fabricated by metamorphic epitaxial growth processes and having a combined doped graded buffer and active layer is merely exemplary in nature, and is in no way intended to limit the invention or its applications or uses. For example, the combined graded buffer and sub-collector layer has particular application for a heterojunction bipolar transistor. However, the teachings of the present invention may have application for other types of semiconductor devices. Further, the specific materials described herein are byway of example in that any ternary system materials or group Ill-V materials may be applicable.

FIG. 2 is a side view of a HBT device 30 similar to the HBT device 10, where like elements are identified by the same reference numeral, according to an embodiment of the present invention. In this embodiment, the undoped graded buffer layer 14 and the sub-collector layer 16 are removed, and replaced with a combined graded buffer and sub-collector layer 32 that is doped. The layer 32 is doped to provide the desired composition of semiconductor materials suitable for the sub-collector of an HBT and the layer 32 is graded in a manner suitable for the composition of the substrate 12 and the composition of the collector layer 18. In this non-limiting embodiment, the combined graded buffer and sub-collector layer 32 is less than 5000 Å thick and is doped with silicon at 2×10¹⁹. Also, the portion of the combined graded buffer and sub-collector layer 32 proximate the substrate 12 is InP and includes a concentration of indium of about 52%, and the portion of the combined graded buffer and sub-collector layer 32 proximate the collector layer 18 is In_{0.86}Al_{0.14}As, where the concentration of indium is about 86%. Other concentrations of indium can be used within the scope of the present invention.

Providing the combined graded buffer and sub-collector layer 32 offers a number of advantages, such as low turn on voltage, low operating voltage and high speed. Further, because the active layers of the HBT 30, particularly the collector layer 18, the base layer 20 and the emitter layer 22, are closer to the thermal conducting portions of the device below the substrate 12, the thermal load on the HBT device 30 is reduced because heat can be removed more quickly.

Providing a combined graded buffer and active layer as discussed above will also have advantages for other semiconductor devices, such as high electron mobility transistors (HEMT) and opto-electronic devices, and where the graded buffer layer is combined with other semiconductor active layers besides a sub-collector layer.

As discussed above, the HBT device 30 is fabricated by metamorphic epitaxial growth processes. The combined graded buffer and sub-collector layer 32 is strain engineered with an aggressive grading rate to comply with the thickness requirement of an HBT sub-collector layer and growth conditions, i.e., temperature, growth interruption, arsenic over pressure, etc., and was optimized to reduce surface threading disclocation density, as well as surface roughness to minimize defect impact on device performance. Through graded buffer design optimization, the thickness of the HBT epitaxial layers can be reduced to provide processes compatible with mature GaAs and InP HBT devices. The metamorphic epitaxial process is able to provide an HBT having a 6.0 Å lattice parameter on an InP substrate with an integrated thin graded buffer layer.

In the present invention, the metamorphic layers with different doping profiles and ternary materials alloy compositions were optimized as the HBT device sub-collector and collector active layers to provide semi-insulating virtual platforms.

By reducing the thickness of the combined graded buffer and sub-collector layer 32, the active region of the HBT device 30 can be provided closer to the substrate 12. Because the substrate 12 has a higher thermal conductivity than the graded buffer layers, the thermal mass provided by the graded buffer and sub-collector layer 32 can be minimized. Further, as the frequency of HBT device 30 increases, the device 30 has to be further isolated so that there is not cross-talk between devices. This requires an etch through the combined graded buffer and sub-collector layer 32 down to the semi-insulating substrate 12 to electrically isolate the devices on a common substrate. Thus, by reducing the thickness of the grade buffer layer by providing the combined graded buffer and sub-collector layer 32, the ability to match processes with mature GaAs and InP HBT fabrication processes can be provided without additional steps. Thus, the processes for fabricating the HBT device 30 is more compatible with other high frequency device fabrication techniques that do not have a high indium content in the base layer.

The foregoing discussion discloses and describes merely exemplary embodiments of the present invention. One skilled in the art will readily recognize from such discussion, and from the accompanying drawings and claims, that various changes, modifications and variations can be made therein without departing from the spirit and scope of the invention as defined in the following claims.

What is Claimed is:

1. A semiconductor device comprising:
a substrate;
a combined graded buffer and active layer deposited on the substrate; and
other semiconductor active layers deposited on the combined layer.

2. The semiconductor device according to claim 1 wherein the combined graded buffer and active layer has a thickness less than 5000 Å.

3. The semiconductor device according to claim 1 wherein the combined graded buffer and active layer is doped.

4. The semiconductor device according to claim 1 wherein the combined graded buffer and active layer is deposited by a metamorphic epitaxial growth process.

5. The semiconductor device according to claim 1 wherein the combined graded buffer and active layer is a combined graded buffer and sub-collector layer, and wherein the other semiconductor active layers include a collector layer deposited on the combined graded buffer and sub-collector layer, a base layer deposited on the collector layer, and an emitter layer deposited on the base layer.

6. The semiconductor device according to claim 5 wherein the device is a heterojunction bipolar transistor.

7. The semiconductor device according to claim 1 wherein the substrate is an indium phosphide or gallium arsenide substrate.

8. The semiconductor device according to claim 7 wherein the combined graded buffer and active layer has a graded composition of indium phosphide proximate the substrate and indium-aluminum-arsenide opposite to the substrate.

9. The semiconductor device according to claim 8 wherein the concentration of indium in the combined graded buffer and active layer proximate the substrate is about 52% and the composition of indium in the combined graded buffer and active layer opposite to the substrate is up to 100%.

10. A heterojunction bipolar transistor comprising:
a semi-insulating substrate;
a combined and doped graded buffer and sub-collector layer deposited on the substrate by a metamorphic epitaxial growth process, wherein the combined graded buffer and sub-collector layer has a thickness less than 5000 Å;
a collector layer deposited on the combined graded buffer and sub-collector layer;
a base layer deposited on the collector layer; and
an emitter layer deposited on the base layer.

11. The transistor according to claim 10 wherein the semi-insulating substrate is an indium phosphide substrate.

12. The transistor according to claim 11 wherein the combined graded buffer and sub-collector layer has a graded composition of indium phosphide proximate the substrate and indium-aluminum-arsenide proximate the collector layer.

13. The transistor according to claim 12 wherein the concentration of indium in the combined graded buffer and sub-collector layer proximate the substrate is about 52% and the composition of indium in the combined graded buffer and sub-collector layer proximate the collector layer is up to 100%.

14. A method for fabricating a semiconductor device, said method comprising:
providing a substrate;
depositing a doped combined graded buffer and active layer on the substrate by a metamorphic epitaxial growth process; and
depositing other semiconductor layers on the combined layer.

15. The method according to claim 14 wherein depositing the combined graded buffer and active layer includes depositing the combined graded buffer and active layer to a thickness less than 5000 Å.

16. The method according to claim 14 wherein the substrate is an indium phosphide substrate.

17. The method according to claim 16 wherein depositing the combined graded buffer and active layer includes depositing a combined graded buffer and active layer with a graded composition of indium phosphide proximate the substrate and indium-aluminum-arsenide opposite to the substrate.

18. The method according to claim 17 wherein the concentration of indium in the combined graded buffer and active layer proximate the substrate is about 52% and the composition of indium in the combined graded buffer and active layer opposite the substrate is about 86%.

19. The method according to claim 14 wherein depositing the combined graded buffer and active layer includes depositing a combined graded buffer and sub-collector layer and depositing other semiconductor layers on the combined layer includes depositing a collector layer on the combined graded buffer and sub-collector layer, depositing a base layer on the collector layer, and depositing an emitter layer on the base layer.

20. The method according to claim 19 wherein the semiconductor device is a heterojunction bipolar transistor.
